(19) United States
(12) Patent Application Publication
(10) Pub. No.: US 2026/0282949 A1
(43) Pub. Date: Sep. 17, 2026

(54) SEMICONDUCTOR PACKAGE HAVING INTERNAL ISOLATION AND COPPER HEAT SPREADER

(71) Applicant: ALPHA AND OMEGA SEMICONDUCTOR INTERNATIONAL LP, TORONTO (CA)

(72) Inventors: Zhiqiang Niu, Santa Clara, CA (US); Jia-long Yuan, Shanghai (CN); Bum-Seok Suh, Seongnam-City (KR); Heng Li, Taoyuan City (TW); Xiaorong Ge, Pleasanton, CA (US)

(73) Assignee: ALPHA AND OMEGA SEMICONDUCTOR INTERNATIONAL LP, TORONTO, ON (CA)

(21) Appl. No.: 19/080,764

(22) Filed: Mar. 14, 2025

(51) Int. Cl. H01L 23/495; H01L 23/31; H01L 23/367; H01L 23/373

(52) U.S. Cl. CPC H10W 70/461; H10W 40/22; H10W 40/255; H10W 70/457; H10W 70/465; H10W 74/111

(57) ABSTRACT

A semiconductor package comprising a composite layer, a lead frame, a first semiconductor device, a second semiconductor device, and a molding encapsulation. The lead frame comprises a plurality of leads and a copper heat spreader. A lead frame strip comprises a plurality of lead frames and a plurality of interim members. Each lead frame of the plurality of lead frames comprises a plurality of leads and a copper heat spreader. Each interim member of the plurality of interim members comprises a lower section, a slanted section, and an upper section.

### FIELD OF THE INVENTION

This invention relates generally to a semiconductor package and a lead frame strip of making the same. More particularly, the present invention relates to a semiconductor package having internal isolation and a copper heat spreader.

### BACKGROUND OF THE INVENTION

Conventional transistor outline 247 (TO-247) package (for example, the package disclosed in US Patent Application Publication No. 2024/0363478 to Bhatt et al.) does not include a copper heat spreader.

The present invention discloses a semiconductor package comprising a copper heat spreader. The advantage of instant disclosure includes lower cost, better heat dissipation, larger die paddle top surface areas, reduced direct bonding copper (DBC) size, lower mechanical stresses, and stronger mechanical support during a molding process.

### SUMMARY OF THE INVENTION

The present invention discloses a semiconductor package comprising a composite layer, a lead frame, a first semiconductor device, a second semiconductor device, and a molding encapsulation. The lead frame comprises a plurality of leads and a copper heat spreader.

A lead frame strip comprises a plurality of lead frames and a plurality of interim members. Each lead frame of the plurality of lead frames comprises a plurality of leads and a copper heat spreader. Each interim member of the plurality of interim members comprises a lower section, a slanted section, and an upper section.

### BRIEF DESCRIPTION OF THE DRAWINGS

FIG. 1A is a top perspective view, and FIG. 1B is a bottom perspective view of a semiconductor package in examples of the present disclosure.

FIG. 2A is a top view, and FIG. 2B is a side view of the semiconductor package, with a molding encapsulation shown in transparent, in one example of the present disclosure. FIG. 2C is a top view of the semiconductor package, without a molding encapsulation, in another example of the present disclosure.

FIG. 3 is a top perspective view of the semiconductor package, without showing the molding encapsulation, in examples of the present disclosure.

FIG. 4A is a top view, FIG. 4B is a cross-sectional view, and FIG. 4C is another cross-sectional view, of a lead frame strip in examples of the present disclosure.

FIG. 5 is a top perspective view of a lead frame strip in examples of the present disclosure.

FIG. 6 is a top perspective view of a lead frame strip and a plurality of composite layers in examples of the present disclosure.

### DETAILED DESCRIPTION OF THE INVENTION

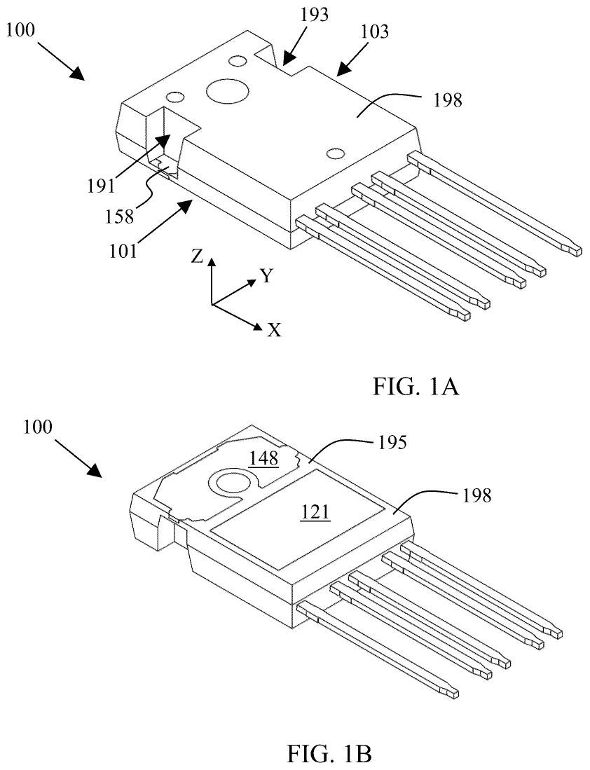

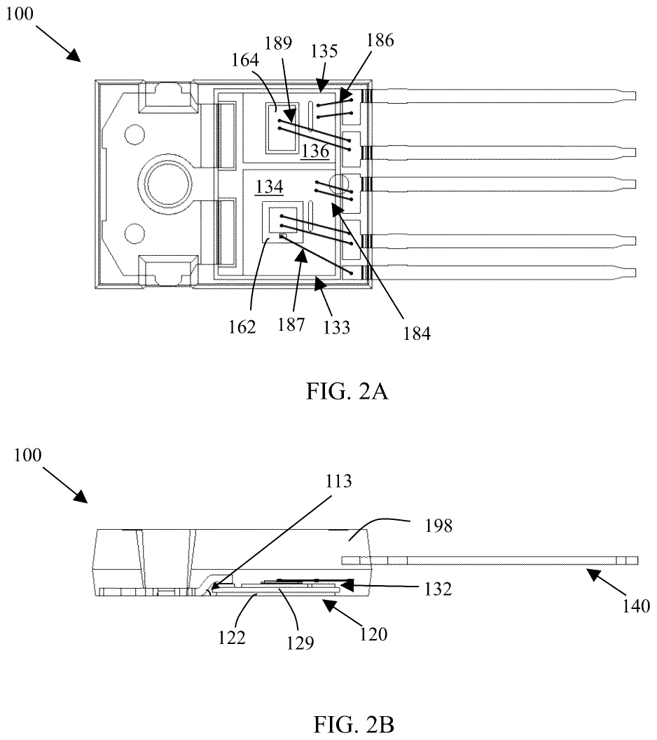

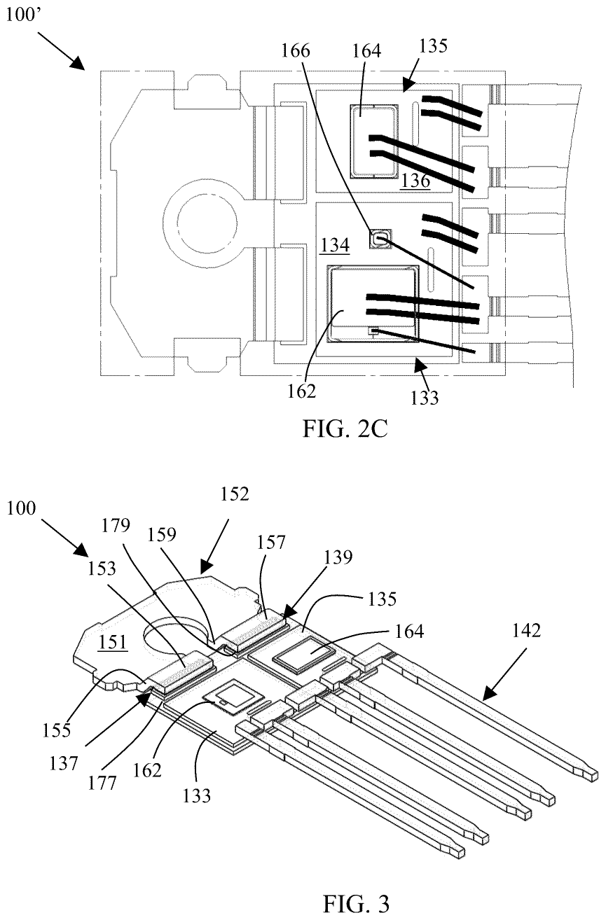

FIG. 1A is a top perspective view, and FIG. 1B is a bottom perspective view of a semiconductor package 100 in examples of the present disclosure. FIG. 2A is a top view, and FIG. 2B is a side view of the semiconductor package 100, with a molding encapsulation 198 shown in transparent, in examples of the present disclosure. FIG. 3 is a top perspective view of the semiconductor package 100, without showing the molding encapsulation 198, in examples of the present disclosure. The semiconductor package 100 comprises a composite layer 120, a lead frame 140, a first semiconductor device 162, a second semiconductor device 164, and the molding encapsulation 198. In examples of the present disclosure, the semiconductor package 100 is a transistor outline 247 (TO-247) package.

In examples of the present disclosure, the composite layer 120 is formed by a DBC process. The composite layer 120 comprises a bottom copper layer 122, a top copper layer 132, and a ceramic layer 129 between the bottom copper layer 122 and the top copper layer 132. The top copper layer 132 comprises a first die paddle 133, a second die paddle 135 electrically isolated from the first die paddle 133, a first connection paddle 137, and a second connection paddle 139. In examples of the present disclosure as shown, the first connection paddle 137, and the second connection paddle 139 are disposed near a top edge of the top copper layer 132 and separate from each other. In other examples not shown, the first connection paddle 137 and the second connection paddle 139 may be connected together and/or connected to one of the first die paddle 133 and the second die paddle 135.

The lead frame 140 comprises a plurality of leads 142 disposed adjacent to a bottom edge of the top copper layer 132 opposite the top edge of the top copper layer 132 and a copper heat spreader 152 disposed adjacent to the top edge of the top copper layer 132. In one example of the disclosure, the plurality of leads 142 are separated from the composite layer 120. In another example of the disclosure, the plurality of leads 142 are separated from the first die paddle 133 and the second die paddle 135 of the top copper layer 132 of the composite layer 120.

The copper heat spreader 152 comprises a body 151, a first elevated portion 153, a first bent portion 155, a second elevated portion 157, and a second bent portion 159. The first elevated portion 153 is attached to the first connection paddle 137 of the top copper layer 132 of the composite layer 120. The first bent portion 155 connects the first elevated portion 153 to the body 151. The second elevated portion 157 is attached to the second connection paddle 139 of the top copper layer 132 of the composite layer 120. The second bent portion 159 connects the second elevated portion 157 to the body 151. In examples of the present disclosure, a respective thickness (along Z-direction) of each lead of the plurality of leads 142 of the lead frame 140 is the same as a thickness of the body 151 of the copper heat spreader 152 of the lead frame 140. In examples of the present disclosure, bottom surface 148 of the body 151 of the copper heat spreader 152 of the lead frame 140 is coplanar to the bottom copper layer 122 of the composite layer 120.

The first elevated portion 153 of the copper heat spreader 152 is attached to the first connection paddle 137 of the top copper layer 132 of the composite layer 120 by a first solder material 177. The second elevated portion 157 of the copper heat spreader 152 is attached to the second connection paddle 139 of the top copper layer 132 of the composite layer 120 by a second solder material 179. In examples of the present disclosure, the first elevated portion 153 and the second elevated portion 157 of the copper heat spreader 152 are separated by a gap therebetween. Alternatively, the first elevated portion 153 and the second elevated portion 157 of the copper heat spreader 152 may be connected without separation.

The first semiconductor device 162 is attached to the first die paddle 133 of the top copper layer 132 of the composite layer 120. The second semiconductor device 164 is attached to the second die paddle 135 of the top copper layer 132 of the composite layer 120. In one example of the present disclosure, the first semiconductor device 162 is a first MOSFET and the second semiconductor device 164 is a second MOSFET. In another example of the present disclosure, the first semiconductor device 162 is a MOSFET and the second semiconductor device 164 is a diode. In another example of the present disclosure, the first semiconductor device 162 is an insulated-gate bipolar transistor (IGBT) and the second semiconductor device 164 is a diode. In another example of the present disclosure shown in FIG. 2C, the semiconductor package 100′ further comprises a third semiconductor device 166 attached to the first die paddle 133. In one example shown in FIG. 2C, the third semiconductor device 166 is a diode. In yet another example of the present disclosure, the third semiconductor device is stacked on top of the first semiconductor device (not shown).

The molding encapsulation 198 encloses the first semiconductor device 162, the second semiconductor device 164, a majority portion of the composite layer 120, a majority portion of the copper heat spreader 152, and a minority portion of the plurality of leads 142. The third semiconductor device 166 if present is also enclosed in the molding encapsulation. A majority portion refers to larger than 50%. A minority portion refers to less than 50%. In examples of the present disclosure, the molding encapsulation 198 further encloses a plurality of bond wires.

In examples of the present disclosure, the plurality of bond wires comprise one or more bond wires 184 and one or more bond wires 186. Each of the one or more bond wires 184 directly connects the first die paddle 133 to a respective one of the plurality of leads 142. Each of the one or more bond wires 186 directly connects the second die paddle 134 to a respective one of the plurality of leads 142. One or more bond wires 187 directly connect the first semiconductor device 162 to one or more leads of the plurality of leads 142. One or more bond wires 189 directly connect the second semiconductor device 164 to one of the plurality of leads 142.

In examples of the present disclosure, a width (along Y-direction) of the semiconductor package 100 is 15.8 mm. A length (along X-direction) of the semiconductor package is 40.98 mm. A sum of a top surface area 134 of the first die paddle 133 of the top copper layer 132 of the composite layer 120 and a top surface area 136 of the second die paddle 135 of the top copper layer 132 of the composite layer 120 is larger than 90 mm². In one example, the sum of the top surface area 134 of the first die paddle 133 of the top copper layer 132 of the composite layer 120 and the top surface area 136 of the second die paddle 135 of the top copper layer 132 of the composite layer 120 is 92 mm². This sum of the top surface area 134 and the top surface area 136 is increased from 72 mm² of a conventional TO-247 package to larger than 90 mm² because the plurality of leads 142 are separated from the composite layer 120 and because of direct wire bonding.

The molding encapsulation 198 comprises a first recess 191 and a second recess 193. The first recess 191 is located at a first side 101 of the semiconductor package 100. The second recess 193 is located at a second side 103 of the semiconductor package 100 opposite the first side 101 of the semiconductor package 100. In examples of the present disclosure, the first recess 191 is directly above a portion of the copper heat spreader 152. The second recess 193 is directly above another portion of the copper heat spreader 152.

In one example, a shape of a bottom of the first recess 191 of the molding encapsulation 198 is of a rectangular shape. A shape of a bottom of the second recess 193 of the molding encapsulation 198 is of the rectangular shape. In another example, a shape of a bottom of the first recess 191 of the molding encapsulation 198 is of a semicircle shape. A shape of a bottom of the second recess 193 of the molding encapsulation 198 is of the semicircle shape.

A first portion 158 of a top surface of the copper heat spreader 152 of the lead frame 140 is exposed from the first recess 191 of the molding encapsulation 198. A second portion of the top surface of the copper heat spreader 152 of the lead frame 140 is exposed from the second recess 193 of the molding encapsulation 198. During a molding process, a first press tool is pressed on the first portion 158 and a second press tool is pressed on the second portion. The copper heat spreader 152 is mechanically stronger than the composite layer 120 thereby providing a better mechanical support under the pressure of the first press tool and the second press tool.

A thickness (along Z-direction) of the semiconductor package 100 is 5,000 microns. A thickness (along Z-direction) of the ceramic layer 129 of the composite layer 120 is less than 400 microns. The thickness (along Z-direction) of the ceramic layer 129 of the composite layer 120 is 380 microns. Because during a molding process, a first press tool is pressed on the first portion 158 of a top surface of the copper heat spreader 152 (rather than on the composite layer 120) and a second press tool is pressed on the second portion, the thickness of the ceramic layer 129 can be reduced from 500 microns of a conventional TO-247 package to less than 400 microns. The advantage of reduced thickness of the ceramic layer 129 includes reduced stresses in the first bent portion 155 due to a reduced angle 113, between a slope of a centerline of the first bent portion 155 and the X-direction, of FIG. 2B and cost savings.

A bottom surface 148 of the body 151 of the copper heat spreader 152 of the lead frame 140 is exposed from a bottom surface 195 of the molding encapsulation 198 so as to facilitate heat dissipation. A bottom surface 121 of the bottom copper layer 122 of the composite layer 120 is exposed from the bottom surface 195 of the molding encapsulation 198 so as to facilitate heat dissipation.

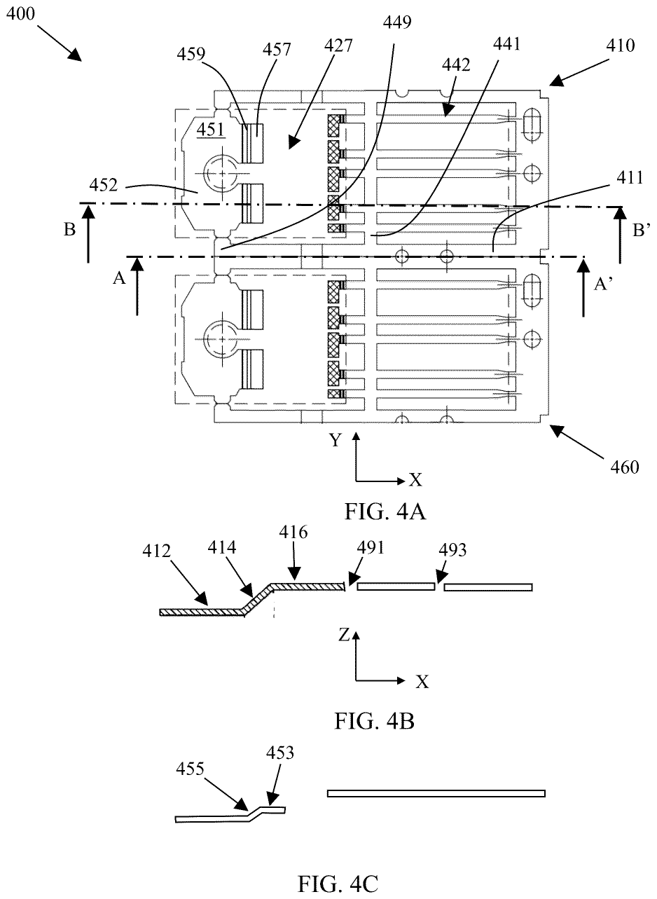

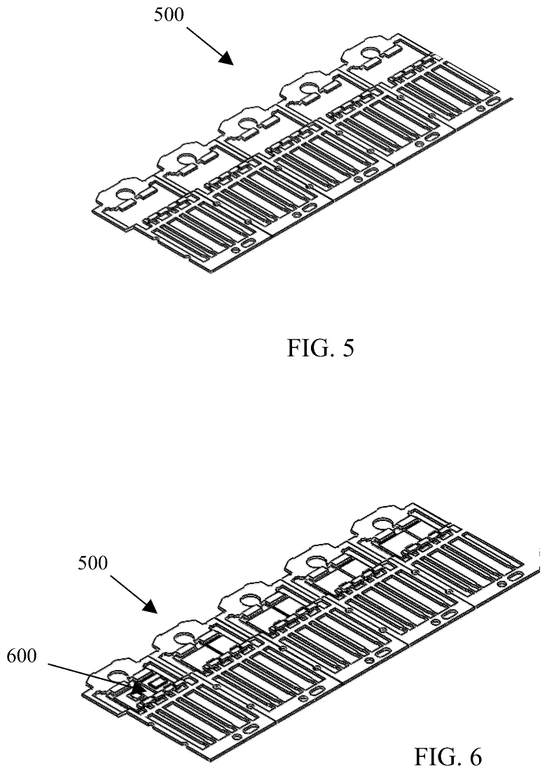

FIG. 4A is a top view, FIG. 4B is a cross-sectional view, and FIG. 4C is another cross-sectional view, of a lead frame strip 400 in examples of the present disclosure. FIG. 5 is a top perspective view of a lead frame strip 500 in examples of the present disclosure. FIG. 6 is a top perspective view of the lead frame strip 500 and a plurality of composite layers 600 in examples of the present disclosure. FIG. 4B is viewed along a direction perpendicular to the AA′ surface of FIG. 4A. FIG. 4C is viewed along a direction perpendicular to the BB′ surface of FIG. 4A

Although the lead frame strip 400 of FIG. 4A comprises a first lead frame 410 and a second lead frame 460. A number of lead frames in a lead frame strip may vary. Although the lead frame strip 500 of FIGS. 5 and 6 comprises five lead frames. A number of lead frames in a lead frame strip may vary.

The first lead frame 410 comprises a plurality of leads 442 and a copper heat spreader 452. A respective thickness (along Z-direction) of each lead of the plurality of leads 442 of the first lead frame 410 is the same as a thickness of the body 451 of the copper heat spreader 452 of the first lead frame 410.

The copper heat spreader 452 comprises a body 451, a first elevated portion 453, a first bent portion 455, a second elevated portion 457, and a second bent portion 459. The first bent portion 455 connects the first elevated portion 453 to the body 451. The second bent portion 459 connects the second elevated portion 457 to the body 451.

The first lead frame 410 further comprises a slot 427 configured to receive a majority portion of a composite layer 120 of FIG. 2B. The composite layer 120 of FIG. 2B comprises a bottom copper layer 122, a top copper layer 132, and a ceramic layer 129 between the bottom copper layer 122 and the top copper layer 132. The top copper layer 132 comprises a first die paddle 133, a second die paddle 135, a first connection paddle 137, and a second connection paddle 139.

The lead frame strip 400 further comprises a plurality of interim members comprising an interim member 411. The plurality of leads 442 are connected to the interim member 411 by a tie bar 441. The body 451 is connected to the interim member 411 by a tie bar 449. The interim member 411, the tie bar 441, and the tie bar 449 will be removed during a singulation process before forming a plurality of semiconductor packages (for example, the semiconductor package 100 of FIG. 1A).

The interim member 411 comprises a lower section 412, a slanted section 414, and an upper section 416. A bottom surface of the lower section 412 of the interim member 411 and a bottom surface of the body 451 of the copper heat spreader 452 are coplanar. A top surface of the upper section 416 of the interim member 411 and a top surface of a selected lead of the plurality of leads 442 are coplanar.

The upper section 416 of the interim member 411 further comprises a first alignment hole 491 and a second alignment hole 493.

Those of ordinary skill in the art may recognize that modifications of the embodiments disclosed herein are possible. For example, straight leads in TO-247 package may be bended to form surface mount package. Other modifications may occur to those of ordinary skill in this art, and all such modifications are deemed to fall within the purview of the present invention, as defined by the claims.

1. A semiconductor package comprising:
a composite layer comprising:
a bottom copper layer,
a top copper layer comprising:
a first die paddle,
a second die paddle,
a first connection paddle, and
a second connection paddle, and
a ceramic layer between the bottom copper layer and the top copper layer,
a lead frame comprising
a plurality of leads separated from the first die paddle and the second die paddle of the top copper layer of the composite layer,
a copper heat spreader comprising:
a body,
a first elevated portion attached to the first connection paddle of the top copper layer of the composite layer,
a first bent portion connecting the first elevated portion to the body,
a second elevated portion attached to the second connection paddle of the top copper layer of the composite layer, and
a second bent portion connecting the second elevated portion to the body,
a first semiconductor device attached to the first die paddle of the top copper layer of the composite layer,
a second semiconductor device attached to the second die paddle of the top copper layer of the composite layer, and
a molding encapsulation enclosing the first semiconductor device, the second semiconductor device, a majority portion of the composite layer, a majority portion of the copper heat spreader, and a minority portion of the plurality of leads.

2. The semiconductor package of claim 1, wherein the first elevated portion and the second elevated portion are separate by a gap.

3. The semiconductor package of claim 1 further comprising:
one or more bond wires directly connecting the first die paddle of the top copper layer of the composite layer to one of the plurality of leads; and
one or more bond wires directly connecting the second die paddle of the top copper layer of the composite layer to one of the plurality of leads.

4. The semiconductor package of claim 3, wherein the molding encapsulation further encloses the bond wires.

5. The semiconductor package of claim 3, wherein a width of the semiconductor package is 15.8 millimeters;
wherein a length of the semiconductor package is 40.98 millimeters; and
a sum of a top surface area of the first die paddle of the top copper layer of the composite layer and a top surface area of the second die paddle of the top copper layer of the composite layer is larger than 90 millimeter square.

6. The semiconductor package of claim 5, wherein the sum of the surface area of the first die paddle of the top copper layer of the composite layer and the surface area of the second die paddle of the top copper layer of the composite layer is at least 92 millimeter square.

7. The semiconductor package of claim 1, wherein the first elevated portion of the copper heat spreader is attached to the first connection paddle of the top copper layer of the composite layer by a first solder material; and
wherein the second elevated portion of the copper heat spreader is attached to the second connection paddle of the top copper layer of the composite layer by a second solder material.

8. The semiconductor package of claim 1, wherein the molding encapsulation comprises:
a first recess located at a first side of the semiconductor package, and
a second recess located at a second side of the semiconductor package opposite the first side of the semiconductor package.

9. The semiconductor package of claim 8, wherein a first portion of a top surface of the copper heat spreader of the lead frame is exposed from the first recess of the molding encapsulation, and
wherein a second portion of the top surface of the copper heat spreader of the lead frame is exposed from the second recess of the molding encapsulation.

10. The semiconductor package of claim 9, wherein a thickness of the semiconductor package is five thousand microns; and
wherein a thickness of the ceramic layer of the composite layer is less than four hundred microns.

11. The semiconductor package of claim 10, wherein the thickness of the ceramic layer of the composite layer is three hundred and eighty microns.

12. The semiconductor package of claim 8, wherein a shape of a bottom of the first recess of the molding encapsulation is of a rectangular shape, and
wherein a shape of a bottom of the second recess of the molding encapsulation is of the rectangular shape.

13. The semiconductor package of claim 1, wherein a bottom surface of the copper heat spreader of the lead frame is exposed from a bottom surface of the molding encapsulation.

14. The semiconductor package of claim 1, wherein a bottom surface of the bottom copper layer of the composite layer is exposed from a bottom surface of the molding encapsulation.

15. The semiconductor package of claim 1, wherein a respective thickness of each lead of the plurality of leads of the lead frame is the same as a thickness of the body of the copper heat spreader of the lead frame.

16. The semiconductor package of claim 1, wherein the semiconductor package is a transistor outline 247 (TO-247) package.

17. A semiconductor package comprising:
a composite layer comprising:
a bottom copper layer,
a top copper layer comprising:
a first die paddle,
a second die paddle,
a ceramic layer between the bottom copper layer and the top copper layer,
a lead frame comprising:
a plurality of leads separated from the composite layer,
a first semiconductor device attached to the first die paddle of the top copper layer of the composite layer,
a second semiconductor device attached to the second die paddle of the top copper layer of the composite layer,
each of first one or more bond wires directly connecting the first die paddle of the top copper layer of the composite layer to a respective one of the plurality of leads, each of second one or more bond wires directly connecting the second die paddle of the top copper layer of the composite layer to a respective one of leads of the plurality of leads, and
a molding encapsulation enclosing the first semiconductor device, the second semiconductor device, a majority portion of the composite layer, and a minority portion of the plurality of leads.

18. The semiconductor package of claim 17, wherein the lead frame further comprises:
a copper heat spreader comprising:
a body,
a first elevated portion,
a first bent portion connecting the first elevated portion to the body,
a second elevated portion, and
a second bent portion connecting the second elevated portion to the body,
wherein the molding encapsulation further encloses a majority portion of the copper heat spreader.

19. The semiconductor package of claim 18, wherein the top copper layer of the composite layer further comprises:
a first connection paddle, and
a second connection paddle,
wherein the first elevated portion of the copper heat spreader is attached to the first connection paddle of the top copper layer of the composite layer; and
wherein the second elevated portion of the copper heat spreader attached to the second connection paddle of the top copper layer of the composite layer.

20. The semiconductor package of claim 17, wherein the first semiconductor device is an insulated-gate bipolar transistor (IGBT) and the second semiconductor device is a diode.
